(19) United States
(12) Patent Application Publication
(10) Pub. No.: US 2008/0252834 A1
(43) Pub. Date: Oct. 16, 2008

(54) Thin film transistor, method for fabricating same and liquid crystal display using same

(75) Inventors: Shuo-Ting Yan, Miao-Li (TW); Chao-Yi Hung, Miao-Li (TW)

Correspondence Address: WEI TE CHUNG;FOXCONN INTERNATIONAL, INC., 1650 MEMOREX DRIVE, SANTA CLARA, CA, 95050, US

(73) Assignee: INNOLUX DISPLAY CORP.

(21) Appl. No.: 12/082,801

(22) Filed: Apr. 14, 2008

(30) Foreign Application Priority Data
Apr. 13, 2007 (CN) 200710074015.2

(51) Int. Cl. G02F 1/1333; H01L 21/00; H01L 33/00

(52) U.S. Cl. 349/122; 257/66; 438/30; 257/E21.001; 257/E33.001

(57) ABSTRACT

A thin film transistor includes a substrate, a gate electrode formed on the substrate, a gate insulating layer covering the gate electrode and the substrate, an a-Si layer and a heavily doped a-Si layer on the gate insulating layer, a conductive film formed on the heavily doped a-Si layer, part of the a-Si layer, and the gate insulating layer, and a source electrode and a drain electrode on the conductive film. A work function of the conductive film is greater than a work function of the a-Si layer.

### FIELD OF THE INVENTION

The present invention relates to a thin film transistor (TFT), a method for fabricating the TFT, and a liquid crystal display using the TFT.

### GENERAL BACKGROUND

A liquid crystal display has the advantages of portability, low power consumption, and low radiation, and has been widely used in various portable information products such as notebooks, personal digital assistants (PDAs), video cameras and the like. Furthermore, the liquid crystal display is considered by many to have the potential to completely replace cathode ray tube (CRT) monitors and televisions.

A liquid crystal display usually includes a plurality of pixel units. Each pixel unit includes a common electrode, a pixel electrode, a liquid crystal layer sandwiched between the common electrode and the pixel electrode, and a thin film transistor connecting the pixel electrode and a data line. In a so-called frame (time frame), when the thin film transistor is switched on, a data voltage is applied to the pixel electrode. A common voltage is applied to the common electrode. A voltage difference between the common electrode and the pixel electrode generates an electric field to drive liquid crystal molecules in the liquid crystal layer, whereby the liquid crystal molecules twist and provide anisotropic transmittance of light passing therethrough. Thus the amount of the light penetrating the pixel unit is adjusted by the strength of the electric field. The aggregation of light provided by all the pixel units produces a desired image that is displayed by the liquid crystal display.

The pixel electrode, the common electrode, and the liquid crystal layer sandwiched therebetween form a liquid crystal capacitor. When the thin film transistor is switched off, electric charges are stored in the liquid crystal capacitor during a current frame until a next frame. However, a leakage current of the thin film transistor reduces the amount of electricity stored in the liquid crystal capacitor.

Referring to FIG. 11, a typical thin film transistor 110 used in a liquid crystal display includes a substrate 111, a gate electrode 112 formed on the substrate 111, a gate insulating layer 113 covering the substrate 111 and the gate electrode 112, an amorphous silicon (a-Si) layer 114 formed on the gate insulating layer 113, a heavily doped a-Si layer 115 formed on the a-Si layer 114, a source electrode 116 and a drain electrode 117 formed on the gate insulating layer 113 having the a-Si layer 114 and the heavily doped a-Si layer 115, and a passivation layer 118 formed on the gate insulating layer 113 having the source electrode 116 and the drain electrode 117.

Referring also to FIG. 12, this is a flowchart summarizing an exemplary method for fabricating the thin film transistor 110. The method includes: step S10, providing a substrate; step S11, forming a gate electrode; step S12, forming a gate insulating layer; step S13, forming an a-Si layer and a heavily doped a-Si layer; step S14, forming source/drain electrodes; and step S15, forming a passivation layer.

In step S10, a substrate is provided. In step S11, a gate electrode is deposited on the substrate. In step S12, a gate insulating layer is deposited on the gate electrode and the substrate. In step S13, an a-Si layer is deposited on the gate insulating layer corresponds to the gate electrode. Then a heavily doped a-Si layer is formed on the a-Si layer. The a-Si layer and the heavily doped a-Si layer are etched to form a channel region by a wet etching method. Because the wet etching method is an isotropic etching method, the a-Si layer and the heavily doped a-Si layer are etched sidewise. Therefore, the a-Si layer and the heavily doped a-Si layer both form slopes 119. In step S14, a source/drain metal layer is deposited on the gate insulating layer having the a-Si layer and the heavily doped a-Si layer. The source/drain metal layer is etched to form the source electrode 116 and the drain electrode 117. In step S15, a passivation layer is provided on the source/drain electrodes 116, 117 and the channel region.

However, because the a-Si layer 114 forms the slopes 119 contacting with the source/drain electrodes 116, 117, the a-Si layer 114 and the source electrode 116 form a Schottky Contact, and the a-Si layer 114 and the drain electrode 117 also form a Schottky Contact. Because differences between a work function of the a-Si layer 114 and work functions of the source/drain electrodes 116, 117 are less, energy barriers between the a-Si layer 114 and the source/drain electrodes 116, 117 are less. When voltages of the source/drain electrodes 116, 117 are higher than a voltage of the gate electrode 112, the voltages of the source/drain electrodes 116, 117 are greater than a voltage of the a-Si layer 114, such that a leakage current phenomenon occurs in the thin film transistor 110. The greater the voltage differences between the a-Si layer 114 and the source/drain electrodes 116, 117, the greater the leakage current. The leakage current in the thin film transistor 110 reduces the electric charges stored in the liquid crystal capacitor. Thus, a corresponding pixel unit including the thin film transistor 110 may not be able to keep a desired gray-scale in a frame. When this happens, the display quality of the liquid crystal display may be impaired.

What is needed, therefore, is a thin film transistor that can overcome the above-described problems. What are also needed are a method for fabricating the thin film transistor, and a liquid crystal display using the thin film transistor.

### SUMMARY

In one preferred embodiment, a thin film transistor includes a substrate, a gate electrode formed on the substrate, a gate insulating layer covering the gate electrode and the substrate, an a-Si layer and a heavily doped a-Si layer on the gate insulating layer, a conductive film formed on the heavily doped a-Si layer, part of the a-Si layer, and the gate insulating layer, and a source electrode and a drain electrode on the conductive film. A work function of the conductive film is greater than a work function of the a-Si layer.

Other novel features and advantages will become more apparent from the following detailed description when taken in conjunction with the accompanying drawings. In the drawings, all the views are schematic.

### BRIEF DESCRIPTION OF THE DRAWINGS

FIG. 1 is a top plan view of one pixel region of a liquid crystal display according to a first embodiment of the present invention, the pixel region including a thin film transistor.

FIG. 2 is an enlarged, side, cross-sectional view taken along line II-II of FIG. 1.

FIG. 3 is a flowchart summarizing an exemplary method for manufacturing the thin film transistor of FIG. 1.

FIG. 4 is a side cross-sectional view relating to a step of providing a substrate according to the method of FIG. 3.

FIG. 5 is a side cross-sectional view relating to a step of forming a gate electrode on the substrate according to the method of FIG. 3.

FIG. 6 is a side cross-sectional view relating to a step of forming a gate insulating layer on the substrate having the gate electrode according to the method of FIG. 3.

FIG. 7 is a side cross-sectional view relating to a step of forming a channel region on the gate insulating layer according to the method of FIG. 3.

FIG. 8 is a side cross-sectional view relating to a step of forming a conductive film around the channel region according to the method of FIG. 3.

FIG. 9 is a side cross-sectional view relating to a step of forming a source electrode and a drain electrode on the conductive film according to the method of FIG. 3.

FIG. 10 is a side cross-sectional view relating to a step of forming a passivation layer on the source/drain electrodes and the channel region according to the method of FIG. 3.

FIG. 11 is a side cross-sectional view of a conventional thin film transistor used in a liquid crystal display.

FIG. 12 is a flowchart summarizing a method for fabricating the thin film transistor of FIG. 11.

### DETAILED DESCRIPTION OF PREFERRED EMBODIMENTS

Reference will now be made to the drawings to describe the preferred embodiments in detail.

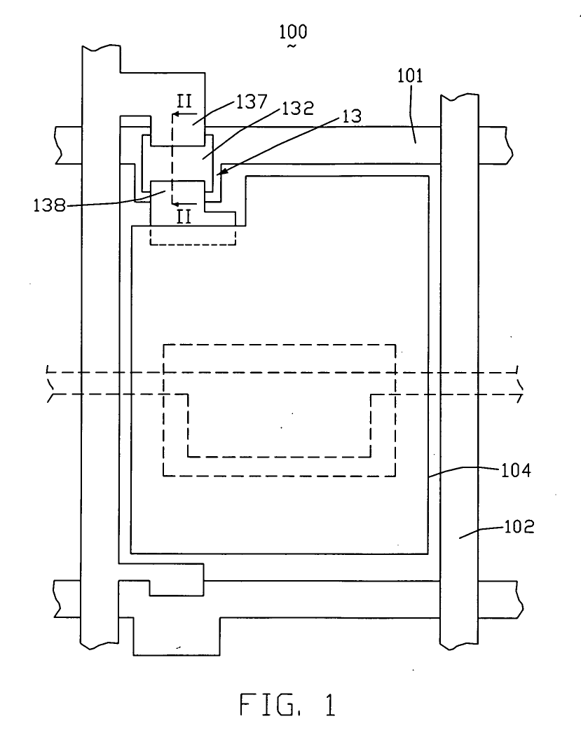

Referring to FIG. 1, one pixel region of a liquid crystal display 100 according to an exemplary embodiment of the present invention is shown. The liquid crystal display 100 includes a plurality of gate lines 101 that are parallel to each other and that each extend along a first direction, a plurality of data lines 102 that are parallel to each other and that each extend along a second direction perpendicular to the first direction, a plurality of thin film transistors 13 provided in the vicinity of points of intersection of the data lines 102 and the gate lines 101, a plurality of pixel electrodes 104, and a plurality of common electrodes (not shown) generally facing the pixel electrodes 104. The gate lines 101 and the data lines 102 define a plurality of pixel regions (only one shown), and the pixel electrodes 104 are provided in the pixel regions respectively. Each thin film transistor 13 includes a gate electrode 132 connected with a corresponding gate line 101, a source electrode 137 connected with a corresponding data line 102, and a drain electrode 138 connected with a corresponding pixel electrode 104.

When a scanning signal is applied to the gate electrode 132 of the thin film transistor 13 via the gate line 101, the thin film transistor 13 is switched on. Then the data line 102 applies a data signal to the pixel electrode 104 via the source electrode 137 and the drain electrode 138 of the thin film transistor 13. At the same time, the common electrode has a common voltage applied thereto. A voltage difference between the common electrode and the pixel electrode 104 forms an electric field. The electric field drives the liquid crystal molecules to orientate to allow a certain quantity of light beams to pass therethrough. The aggregation of light provided by all the pixel units produces a desired image that is displayed by the liquid crystal display 100.

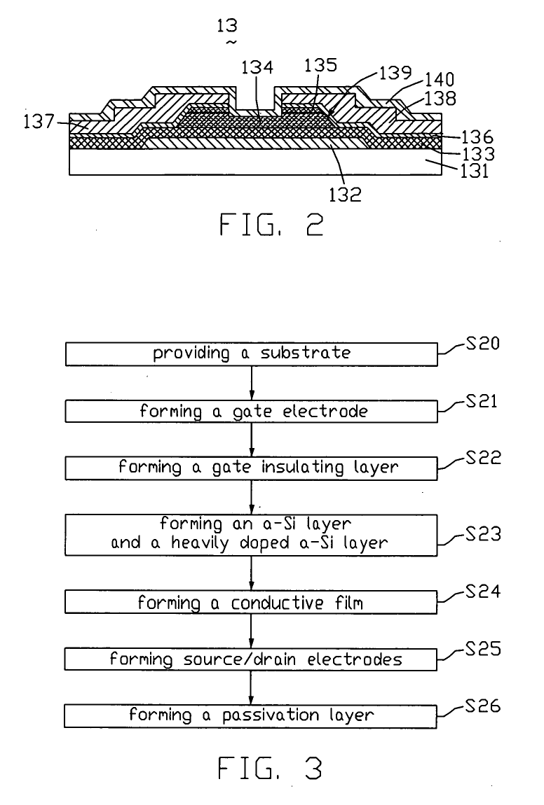

Referring also to FIG. 2, the thin film transistor 13 includes a substrate 131, the gate electrode 132 formed on the substrate 131, a gate insulating layer 133 covering the substrate 131 and the gate electrode 132, an amorphous silicon (a-Si) layer 134 formed on the gate insulating layer 133, a heavily doped a-Si layer 135 formed on the a-Si layer 134, a conductive film 136 formed on the heavily doped a-Si layer 134 and the gate insulating layer 133, the source electrode 137 and the drain electrode 138 formed on the conductive film 136, and a passivation layer 139 formed on the source electrode 137, the drain electrode 138 and the a-Si layer 134.

Referring to FIG. 3, this is a flowchart summarizing an exemplary method for fabricating the thin film transistor 13. For simplicity, the flowchart and the following description are couched in terms that relate to the part of the thin film transistor 13 shown in FIG. 2. The method includes: step S20, providing a substrate; step S21, forming a gate electrode; step S22, forming a gate insulating layer; step S23, forming an a-Si layer and a heavily doped a-Si layer; step S24, forming a conductive film; step S25, forming source/drain electrodes; and step S26, forming a passivation layer.

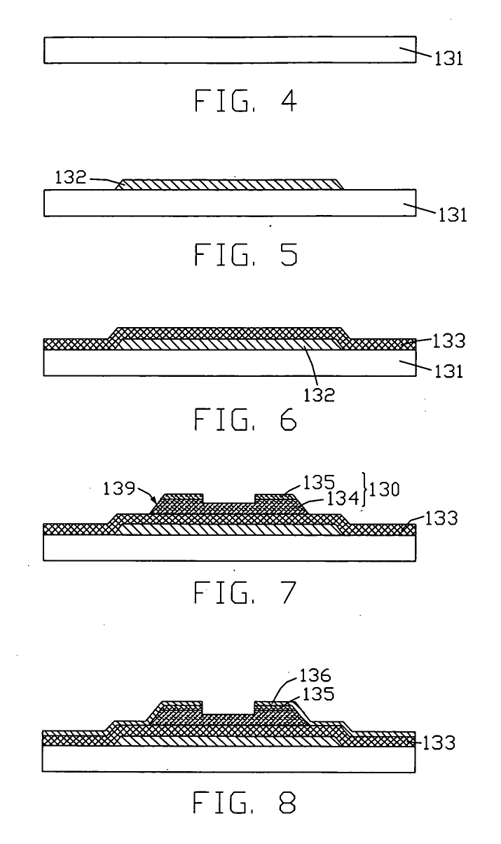

In step S20, referring also to FIG. 4, a substrate 131 is provided. The substrate 131 may be made from glass, quartz or ceramic, for example.

In step S21, referring also to FIG. 5, a gate metal layer is formed on the substrate 131 by a chemical vapor deposition (CVD) process or a physical vapor deposition (PVD) process. A thickness of the gate metal layer is substantially equal to 300 nanometers. A first photo-resist layer is formed on the gate metal layer. A photo-mask (not shown) and an ultraviolet light source (not shown) are provided to expose the first photo-resist layer. The exposed first photo-resist layer is developed, thereby forming a first photo-resist pattern. Using the first photo-resist pattern as a mask, the gate metal layer is etched, thereby forming the gate electrode 132. The first photo-resist pattern is then removed, and the substrate 131 is cleaned and dried. The gate electrode 132 may be made from material including any one or more items selected from the group consisting of aluminum (Al), molybdenum (Mo), copper (Cu), chromium (Cr), and tantalum (Ta).

In step S22, referring also to FIG. 6, a gate insulating layer 133 is deposited on the substrate 131 having the gate electrode 132 by a CVD process. The gate insulating layer 133 can be made from silicon nitride (SiNₓ) or silicon oxide (SiO₂). The form of silicon nitride can for example be SiN_{4/3}, etc.

In step S23, referring also to FIG. 7, an a-Si layer 134 is formed on the gate insulating layer 133 by a CVD process, and a heavily doped a-Si layer 135 is formed on the a-Si layer 134. A second photo-resist layer (not shown) is coated on the heavily doped a-Si layer 135. An ultraviolet (UV) light source (not shown) and a photo-mask (not shown) are used to expose the second photo-resist layer. Then the exposed second photo-resist layer is developed, thereby forming a second photo-resist pattern. Using the second photo-resist pattern as a mask, portions of the a-Si layer 134 and the heavily doped a-Si layer 135 are etched away, and a central portion of the heavily doped a-Si layer 135 and part of a central portion the a-Si layer 134 are etched away, thereby forming a channel region (not labeled). The a-Si layer and the heavily doped a-Si layer 135 are also etched sidewise to form slopes 139.

In step S24, referring also to FIG. 8, a conductive film 136 is coated on the gate insulating layer 133 and the heavily doped a-Si layer 135 by a PVD process. The conductive film 136 contacts the a-Si layer at the slopes 139. A central portion of the conductive film 136 is etched away to expose the channel region. The conductive film 136 has a high work function. The conductive film 136 can for example be made from ITO.

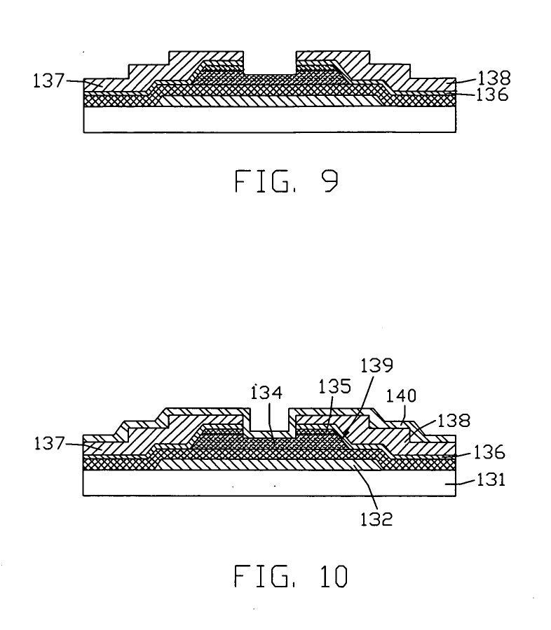

In step S25, referring also to FIG. 9, a source/drain metal layer is deposited on the conductive film 136. The source/drain metal layer may be made from material including any one or more items selected from the group consisting of aluminum, aluminum alloy, molybdenum, tantalum, and molybdenum-tungsten alloy. Then a third photo-resist layer (not shown) is coated on the source/drain metal layer. An ultraviolet (UV) light source (not shown) is used to expose the third photo-resist layer. Then the exposed third photo-resist layer is developed, thereby forming a third photo-resist pattern. After that, a portion of the source/drain metal layer is removed. The third photo-resist pattern is then removed, thereby forming the source electrode 137 and the drain electrode 138.

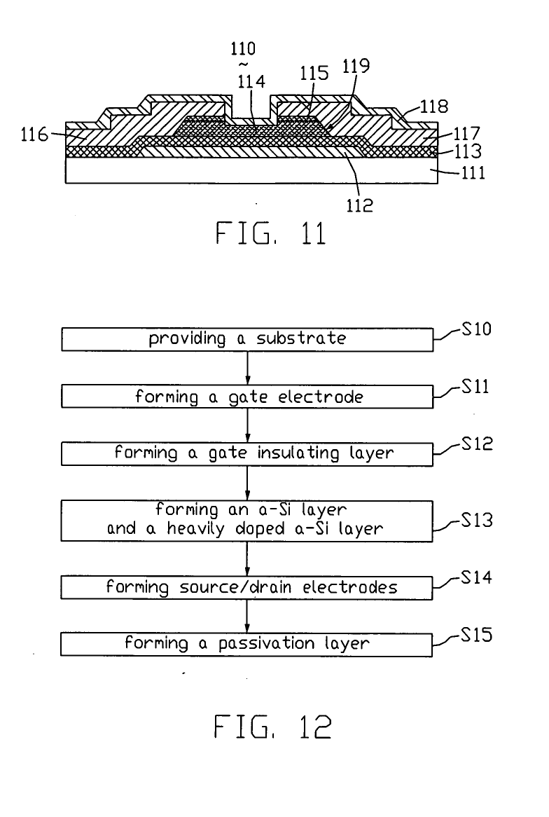

In step S26, referring to FIG. 10, a passivation layer 140 is deposited on the source/drain electrodes 137, 138 and the channel region. Thus, the thin film transistor 13 is obtained.

In summary, compared to the above-described conventional thin film transistor 110, the thin film transistor 13 includes a conductive film 136 separating the a-Si layer 134 from the source/drain electrodes 137, 138. The conductive film 136 has high work function, thus preventing the formation of Schottky Contacts between the a-Si layer 134 and the source/drain electrodes 137, 138. Accordingly, energy barriers between the a-Si layer 134 and the source/drain electrodes 137, 138 are great, and a leakage current of the thin film transistor 13 is reduced. Therefore, the electric charges stored in a corresponding liquid crystal capacitor are able to be substantially kept at a desired level. Accordingly, a display quality of the liquid crystal display 100 is improved.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

Claimed is:

1. A thin film transistor comprising:
a substrate;
a gate electrode formed on the substrate;
a gate insulating layer covering the gate electrode and the substrate;
an a-Si layer and a heavily doped a-Si layer formed on the gate insulating layer;
a conductive film formed on the heavily doped a-Si layer, part of the a-Si layer, and the gate insulating layer; and
a source electrode and a drain electrode formed on the conductive film, a work function of the conductive film being greater than a work function of the a-Si layer.

2. The thin film transistor as claimed in claim 1, wherein the conductive film is made from indium tin oxide.

3. The thin film transistor as claimed in claim 1, wherein a central portion of the a-Si layer on the gate insulating layer defines a blind hole, and a central portion of a heavily doped a-Si layer on the a-Si layer defines a corresponding through hole, and the blind hole and the through hole cooperatively define a channel region.

4. The thin film transistor as claimed in claim 3, wherein the conductive film covers the heavily doped a-Si layer such that the channel region is exposed.

5. The thin film transistor as claimed in claim 3, further comprising a passivation layer covering the source electrode, the drain electrode, and the channel region.

6. The thin film transistor as claimed in claim 1, wherein the substrate is made from one of glass, quartz, and ceramic.

7. The thin film transistor as claimed in claim 1, wherein the gate electrode is made from material including at least one item selected from the group consisting of aluminum, molybdenum, copper, chromium, and tantalum.

8. The thin film transistor as claimed in claim 1, wherein a thickness of the gate electrode is substantially equal to 300 nanometers.

9. The thin film transistor as claimed in claim 1, wherein the gate insulating layer is made from one of silicon nitride and silicon oxide.

10. A method for manufacturing a thin film transistor, the method comprising:
providing a substrate;
forming a gate electrode on the substrate;
forming a gate insulating layer on the gate electrode and the substrate;
forming an a-Si layer and a heavily doped a-Si layer on the gate insulating layer;
forming a conductive film on the heavily doped a-Si layer, part of the a-Si layer, and the gate insulating layer; and
forming a source electrode and a drain electrode on the conductive film.

11. The method for manufacturing a thin film transistor as claimed in claim 10, wherein a work function of the conductive film is greater than a work function of the a-Si layer.

12. The method for manufacturing a thin film transistor as claimed in claim 10, wherein the step of forming an a-Si layer and a heavily doped a-Si layer on the gate insulating layer comprises: forming an a-Si layer on the gate insulating layer, part of a central portion of the a-Si layer being etched away, forming a heavily doped a-Si layer on the a-Si layer, a central portion of the heavily doped a-Si layer being etched away.

13. The method for manufacturing a thin film transistor as claimed in claim 12, wherein the conductive film is formed on the heavily doped a-Si layer, exposing the central portion of the a-Si layer.

14. The method for manufacturing a thin film transistor as claimed in claim 13, further comprising disposing a passivation layer on the source electrode, the drain electrode, and the central portion of the a-Si layer

15. The method for manufacturing a thin film transistor as claimed in claim 10, wherein the conductive film is made from indium tin oxide.

16. A liquid crystal display comprising:
a plurality of parallel gate lines;
a plurality of parallel data lines that are substantially perpendicular to but insulated from the gate lines;
a plurality of thin film transistors provided adjacent to intersections of the gate lines and the data lines, each thin film transistor comprising:
a gate electrode connected with the gate line;
a gate insulating layer covering the gate electrode;
an a-Si layer and a heavily doped a-Si layer formed on the gate insulating layer;
a conductive film formed on the heavily doped a-Si layer, part of the a-Si layer, and the gate insulating layer; and
a source electrode and a drain electrode formed on the conductive film, a work function of the conductive film being greater than a work function of the a-Si layer.

17. The liquid crystal display as claimed in claim 16, wherein the conductive film is made from indium tin oxide.

18. The liquid crystal display as claimed in claim 16, wherein a central portion of the a-Si layer on the gate insulating layer defines a blind hole, and a central portion of a heavily doped a-Si layer on the a-Si layer defines a corresponding through hole, and the blind hole and the through hole cooperatively define a channel region.

19. The liquid crystal display as claimed in claim 18, wherein the conductive film covers the heavily doped a-Si layer such that the channel region is exposed.

20. The liquid crystal display as claimed in claim 18, further comprising a passivation layer covering the source electrode, the drain electrode and the channel region.
